(19) United States
(12) Patent Application Publication
(10) Pub. No.: US 2022/0417668 A1
(43) Pub. Date: Dec. 29, 2022

(54) MEMS Speaker

(71) Applicant: AAC Kaitai Technologies (Wuhan) CO., LTD, Wuhan (CN)

(72) Inventors: Qiang Dan, Shenzhen (CN); Yiwei Zhou, Shenzhen (CN); Shiyang Cheng, Shenzhen (CN); Yang Li, Shenzhen (CN)

(21) Appl. No.: 17/566,717

(22) Filed: Dec. 31, 2021

(30) Foreign Application Priority Data
Jun. 28, 2021 (CN) 202121452590.3

(51) Int. Cl. H04R 19/00; B81B 3/00

(52) U.S. Cl. CPC H04R 19/005; B81B 3/0059; H04R 2201/003; B81B 2201/0257; B81B 2203/0127

(57) ABSTRACT

One of the main objects of the present invention is to provide a MEMS speaker with improved high frequency acoustic performance. To achieve the above-mentioned object, the present invention provides a MEMS speaker including a base with a first cavity and two openings opposite to each other; a substrate covering one of the openings; a diaphragm fixed to the base and covers the other opening; and a MEMS driver. The MEMS driver includes a first support part forming a distance from the diaphragm, a second support part extending from an edge of the first support part toward the diaphragm for supporting the diaphragm, and a piezoelectric member attached to the first support part.

### FIELD OF THE PRESENT DISCLOSURE

The present invention relates to electroacoustic transducers, and more particularly to a MEMS speaker.

### DESCRIPTION OF RELATED ART

As one of the main components of mobile terminals such as mobile phones, the speaker is mainly used to convert electrical signals into sound signals.

MEMS speaker (Micro-Electro-Mechanical System), that is, Micro-Electro-Mechanical System speakers. It mainly includes a base with a cavity, a diaphragm and a driver fixed to the base, and a coupling connector. The diaphragm and the driver are spaced apart to form a temporary cavity. The coupling connector is accommodated in the temporary cavity and one end is connected to the driver and the other end is connected to the diaphragm, and the three can vibrate and produce sound together.

In the related technology, the diaphragm spans one of the surfaces of the base, and the driver is connected to the edge of the other surface of the base. This kind of assembly scheme avoids the difficulty that diaphragm needs to be prepared with MEMS materials and processes. On the basis of using MEMS driver, the mature sounding solution of the traditional diaphragm dome can still be retained.

However, in the related art, the coupling connector is often set as a mass, which can serve as a coupling connector and can be adjusted, but it is mostly connected to the middle position of the diaphragm to support diaphragm vibration. Considering the segmentation vibration at high f0 frequency, the diaphragm cannot be much larger than the mass block, which limits the sound area. If it is required to increase the sound area, the mass shall be increased, resulting in the further increase of the entire driver, the structure f0 will also be significantly reduced, high-frequency performance cannot be guaranteed.

Therefore, it is necessary to provide a new MEMS speaker to solve the above technical problems.

### SUMMARY OF THE PRESENT INVENTION

One of the main objects of the present invention is to provide a MEMS speaker with improved high frequency acoustic performance.

To achieve the above-mentioned objects, the present invention provides a MEMS speaker including a ring-shaped base with a first cavity and two openings opposite to each other; a substrate fixed to the base and covering one of the openings; a diaphragm fixed to the base and covers the other opening; and a MEMS driver accommodated in the base and fixed on a side of the diaphragm facing the substrate for driving the diaphragm to vibrate and produce sound. The MEMS driver includes a first support part forming a distance from the diaphragm, a second support part extending from an edge of the first support part toward the diaphragm for supporting the diaphragm, and a piezoelectric member attached to the first support part.

The MEMS speaker further includes a support member fixed on a side of the substrate facing the diaphragm; the support member is fixedly connected to a middle position of the first support part such that the first support part is spaced from the substrate.

In addition, the second support part is ring shaped and locates at a distance from the base.

In addition, the first support part includes a middle part located at a middle position of the support member, and at least two support beams connecting the middle part and the second support part; the piezoelectric member attaches to the support beam.

In addition, the substrate includes a first substrate located at an intermediate position of the support member, a second substrate spaced around the first substrate, and a connection beam connecting the first substrate and the second substrate; the base is fixed to the second substrate.

In addition, the substrate has two said connection beams for forming an avoidance gap therebetween, and the support beam is configured to be corresponding to the avoidance gap.

In addition, the substrate is a printed circuit board; the support member is made of conductive material; the support member is electrically connected to the piezoelectric member; and the support member is electrically connected to the printed circuit board.

In addition, the MEMS speaker further includes an elastic guide part having a first fixed part fixed to an end of the second support part far from the diaphragm, a second fixed part fixed to the base, and an elastic part connecting the first fixed part and the second fixed part.

In addition, the elastic part includes a plurality of elastic beams each having a U shape, Z shape or S shape.

In addition, the elastic part is a ring structure, and a cross section of the elastic part along a vibration direction of the diaphragm is wave-shaped.

In addition, the MEMS speaker further includes a reinforcing plate fixed to the diaphragm on a side facing the MEMS driver; an end of the second support part away from the first support part is fixed to the reinforcing plate.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is a cross-sectional view of a MEMS speaker in accordance with an exemplary embodiment of the present invention;

FIG. 2 is an isometric view of a part of the MEMS speaker in FIG. 1;

FIG. 3 is a top view of the part in FIG. 2;

FIG. 4 is a cross-sectional view of a MEMS speaker in accordance with another exemplary embodiment;

FIG. 5 is an isometric view of an elastic guide part of the MEMS speaker in FIG. 4;

FIG. 6 is also an isometric view of the elastic guide part;

FIG. 7 is a cross-sectional view of a MEMS speaker in accordance with another exemplary embodiment of the present invention;

FIG. 8 is a cross-sectional view of a MEMS speaker in accordance with another exemplary embodiment of the present invention.

### DETAILED DESCRIPTION OF THE EXEMPLARY EMBODIMENTS

The present disclosure will hereinafter be described in detail with reference to exemplary embodiments. To make the technical problems to be solved, technical solutions and beneficial effects of the present disclosure more apparent, the present disclosure is described in further detail together with the figure and the embodiments. It should be understood the specific embodiments described hereby are only to explain the disclosure, not intended to limit the disclosure.

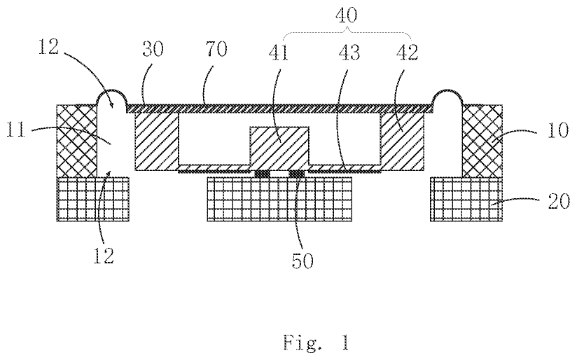

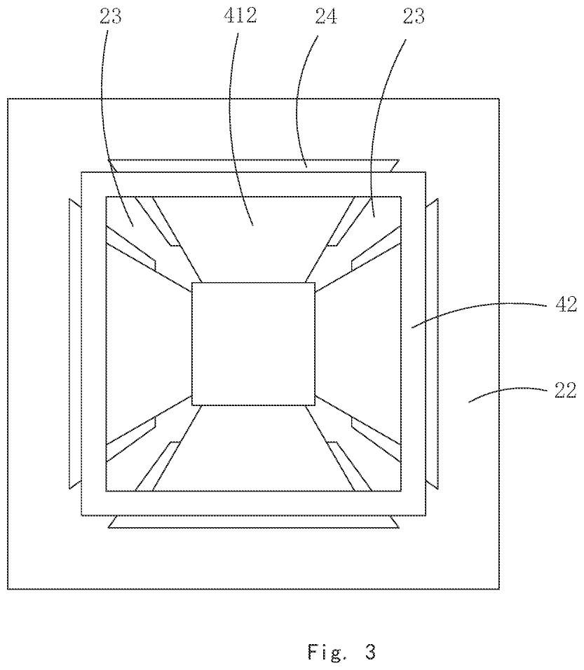

Please refer to FIGS. 1-8. This embodiment provides an MEMS speaker, which includes a base 10, a substrate 20, a diaphragm 30 and MEMS driver 40.

Please refer to FIGS. 1-3, the base 10 is a ring structure with a first cavity 11 and two openings 12 arranged oppositely. The substrate 20 is fixed to the base 10 and covers one of the opening 12. The diaphragm 30 is fixed to base 10 and covers another opening 12. Specifically, the diaphragm 30 is a traditional diaphragm material among common speaker monomers on the market, instead of being fabricated by an MEMS process, which reduces the process difficulty.

The MEMS driver 40 is accommodated in the first cavity 11 of the base 10 and fixed on the side of the diaphragm 30 facing the substrate 20 to drive the diaphragm 30 to vibrate and produce sound. Specifically, the MEMS driver 40 includes a first support part 41 spaced from the substrate 20, a second support part 42 that is bent from the edge of the first support part 41 to the diaphragm 30 to support the diaphragm 30, and the piezoelectric member 43 which is attached to the first support part 41.

When the piezoelectric member 43 receives the electrical signal, it deforms and drives the diaphragm 30 to vibrate through the second support part 42. In the technical solution of the present invention, the MEMS speaker 100 further includes a support member 50 fixed on the side of the substrate 20 facing the diaphragm 30. The support member 50 and the first support part 41 are fixedly connected in the middle position, so that the first support part 41 and the substrate 20 are spaced apart to provide a certain vibration space for the first support part 41. In this embodiment, the first support part 41 is a mass block, so set up, the first support part 41 is supported on the substrate 20 through the support member 50. It effectively suppresses the vibration division of the diaphragm 30 by the first support part 41, which is conducive to designing the diaphragm 30 into a structure with a larger sound area without increasing the mass. Effectively improve the sound performance of the speaker and ensure good high-frequency performance. More preferably, set the second support part 42 to a ring shape. It is helpful to provide stronger support for diaphragm 30, and the second support part 42 and base 10 are set apart. Avoid collision or friction with base 10 when diaphragm 30 vibrates and generate noise, and ensure the good sound performance of MEMS speaker 100.

Specifically, the first support part 41 includes a middle part 411 located in the middle position and fixedly connected to the support member 50, and a support beam 412 connecting the middle part 411 and the second support part 42. In order to ensure the symmetry and stability of the diaphragm 30 vibration, the support beam 412 includes at least two. That is, when two support beams 412 are arranged, the angle between the support beams 412 is 180 degrees. In this embodiment, four support beams 412 are arranged, and the four support beams 412 surround the middle part 411 and are arranged at equal intervals. Wherein, the piezoelectric member 43 is attached to the support beam 412. It is understandable that a piezoelectric member 43 can be attached to each support beam 412. You can also choose part of the support beam 412 to be attached to the piezoelectric member 43, which can be adjusted according to the specific design.

Please refer to FIGS. 1-3. Specifically, the substrate 20 includes a first substrate 21 located at an intermediate position and fixed to the support member 50, a second substrate 22 spaced around the first substrate 21, and a connection beam connecting the first substrate 21 and the second substrate 22 twenty three. The base 10 is fixed to the second substrate 22, and the support member 50 is fixed to the side of the first substrate 21 facing the diaphragm 30. It can be understood that at least two connection beams 23 are arrange, similar to support beams 412. When two connection beams 23 are arranged, the angle between the two connection beams 23 is 180 degrees. When at least three connection beams 23 are arranged, two adjacent connection beams 23 forms an avoidance gap 24 at intervals, and the support beam 412 and the avoidance gap 24 are arranged correspondingly. In this way, the support beam 412 does not interfere with the substrate 20 when vibrating, ensuring good vibration performance and sufficient vibration space.

It can be understood that the substrate 20 is a PCB circuit board, and the support member 50 is a conductive component. The piezoelectric member 43 is electrically connected to the substrate 20 through the support member 50.

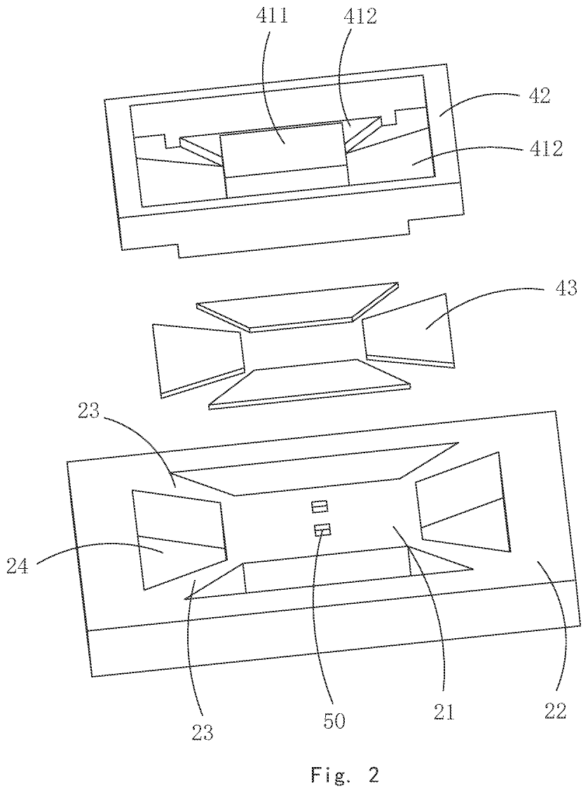

The structure of the MEMS speaker in the present invention will be further described with reference to FIGS. 1 and 2, and the substrate 20 has a rectangular shape. Specifically, the first substrate 21 is a rectangular solid structure, and the second substrate 22 is a hollow ring-shaped rectangular structure. The geometric center of the first substrate 21 and the geometric center of the second substrate 22 overlap. Each connection beam 23 extends from the vertex position of the first substrate 21 to the corner position opposite to the inner side of the second substrate 22;

Similarly, in the MEMS driver 40, the first support part 41 is a solid structure with a rectangular shape, and the second support part 42 is a hollow ring-shaped rectangular structure. The geometric center of the first support part 41 and the geometric center of the second support part 42 overlap. That is, the edges along the major and minor axes of the first support part 41 are parallel to the edges along the major and minor axes of the opposite second support part 42. The support beam 412 extends from an edge of the first support part 41 to a corresponding edge of the second support part 42 connected to it. In this embodiment, the width of the support beam 412 gradually increases from the first support part 41 to the second support part 42 in the extending direction. The avoidance gap 24 mentioned above is designed to avoid the support beam 412. Provide avoidance space for support beam 412 to vibrate in the vertical direction to avoid collision.

The conductive support member 50 is fixed on the first substrate 21, and the height of the conductive component 50 determines the distance between the MEMS driver 40 and the substrate 20. Therefore, the height of the support member 50 can be flexibly adjusted according to the design of the vibration amplitude of the diaphragm 30.

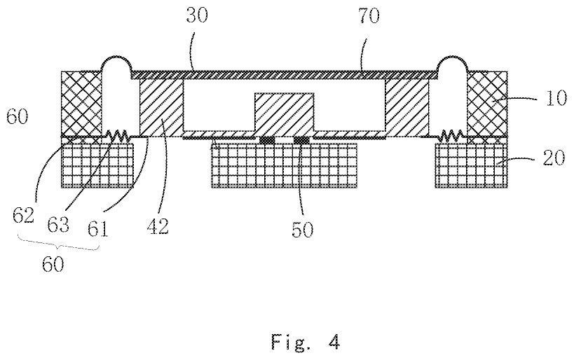

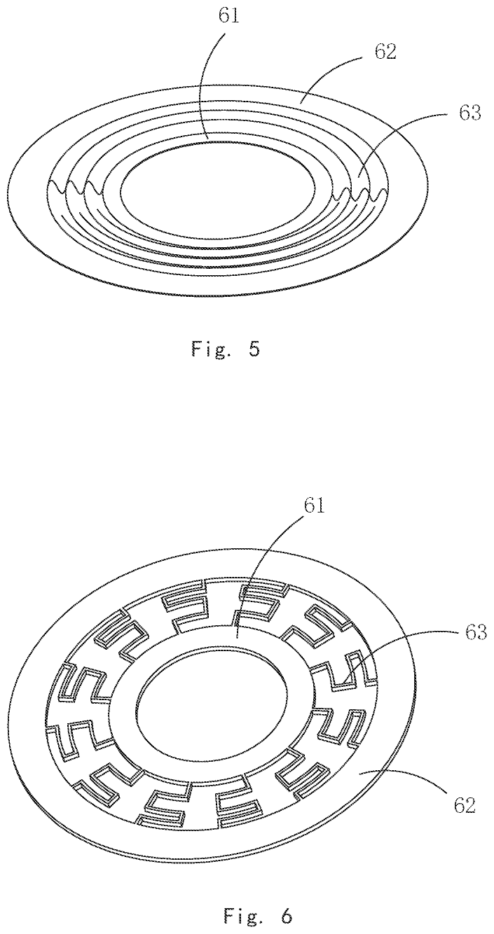

Please refer to FIGS. 4-8, in other embodiment, in order to further enhance the stability of the diaphragm 30 vibration. The MEMS speaker 100 is also equipped with an elastic guide part 60. The elastic guide part 60 includes a first fixed part 61 fixed to the end of the second support part 42 away from the diaphragm 30, a second fixed part 62 fixed to the base 10, and an elastic part 63 connecting the first fixed part 61 and the second fixed part 62. Wherein, the first fixed part 61 is a ring structure. As shown in FIG. 6, the elastic part 63 can be several elastic beam structures. Several elastic beams 63 are arranged at intervals around the first fixed part 61, and their shapes can be U-shaped, Z-shaped, S-shaped, and so on. As shown in FIG. 5, the elastic part 63 can also be a continuous ring structure, and its interface along the vibration direction is wave-shaped. The setting of the elastic guide part 60 can further support the vibration of the diaphragm 30 and improve the vibration stability.

In this embodiment, in order to reduce the vibration interference between the substrate 20 and the MEMS driver 40, it can be achieved by adjusting the height of the support member 50.

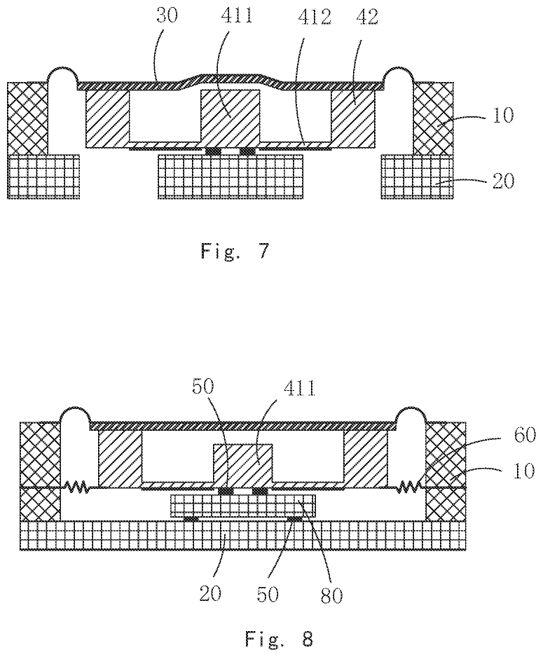

As shown in FIG. 7, in order to meet the design of sufficient amplitude, when the mass of the middle part 411 as the mass block needs to be increased, it may be achieved by increasing its height, which will increase the risk of collision of the middle part 411. Therefore, the position corresponding to the diaphragm 30 and the middle part 411 can be set to arch upward. It not only ensures sufficient vibration sensitivity, but also avoids the risk of collision between middle part 411 and diaphragm 30.

In addition, in the specific design, as shown in FIG. 1, the MEMS speaker also includes a reinforcing plate 70 fixed to the diaphragm 30 on the side facing the MEMS driver 40. The end of the second support part 42 away from the first support part 41 is fixed to the reinforcing plate 70. The reinforcing plate 70 can adjust its vibration performance by increasing its mass.

In addition, the traditional diaphragm 30 material is softer, and the fixing strength between the reinforcing plate 70 and the second support part 42 will be higher.

As shown in FIG. 8, the present invention also provides another embodiment. Wherein, when the thickness of the conductive component 50 cannot separate the substrate 20 and the MEMS driver 40 by a large enough distance, another PCB BOARD 80 can be stacked on the side where the substrate 20 and the base 10 are fixed. Moreover, the PCB BOARD 80 and the substrate 20 are still electrically connected through the conductive component 50. In this way, the setting of PCB BOARD 80 can meet the requirements of large amplitude.

Compared with related technologies, the MEMS speaker of the present invention converts the connection between the MEMS driver and the base from the edge to a fixed connection with the mass at the middle position. The diaphragm is connected to the diaphragm through the second support part located on the outer periphery of the mass block and drives the diaphragm to vibrate and sound. Not only the vibration division of diaphragm by the mass block is effectively suppressed, but the external size of the second support part is significantly larger than that of the mass block. It can support a larger area of diaphragm, which improves SPL and high frequency performance.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A MEMS speaker comprising:
a ring-shaped base with a first cavity and two openings opposite to each other;
a substrate fixed to the base and covering one of the openings;
a diaphragm fixed to the base and covers the other opening;
a MEMS driver accommodated in the base and fixed on a side of the diaphragm facing the substrate for driving the diaphragm to vibrate and produce sound; wherein,
the MEMS driver comprises a first support part forming a distance from the diaphragm, a second support part extending from an edge of the first support part toward the diaphragm for supporting the diaphragm, and a piezoelectric member attached to the first support part; and wherein
the MEMS speaker further comprises a support member fixed on a side of the substrate facing the diaphragm; the support member is fixedly connected to a middle position of the first support part such that the first support part is spaced from the substrate.

2. The MEMS speaker as described in claim 1, wherein, the second support part is ring shaped and locates at a distance from the base.

3. The MEMS speaker as described in claim 1, wherein, the first support part comprises a middle part located at a middle position of the support member, and at least two support beams connecting the middle part and the second support part; the piezoelectric member attaches to the support beam.

4. The MEMS speaker as described in claim 3, wherein, the substrate comprises a first substrate located at an intermediate position of the support member, a second substrate spaced around the first substrate, and a connection beam connecting the first substrate and the second substrate; the base is fixed to the second substrate.

5. The MEMS speaker as described in claim 4, wherein, the substrate has two said connection beams for forming an avoidance gap therebetween, and the support beam is configured to be corresponding to the avoidance gap.

6. The MEMS speaker as described in claim 1, wherein, the substrate is a printed circuit board; the support member is made of conductive material; the support member is electrically connected to the piezoelectric member; and the support member is electrically connected to the printed circuit board.

7. The MEMS speaker as described in claim 1 further comprising an elastic guide part having a first fixed part fixed to an end of the second support part far from the diaphragm, a second fixed part fixed to the base, and an elastic part connecting the first fixed part and the second fixed part.

8. The MEMS speaker as described in claim 7, wherein, the elastic part comprises a plurality of elastic beams each having a U shape, Z shape or S shape.

9. The MEMS speaker as described in claim 8, wherein, the elastic part is a ring structure, and a cross section of the elastic part along a vibration direction of the diaphragm is wave-shaped.

10. The MEMS speaker as described in claim 1, further comprising a reinforcing plate fixed to the diaphragm on a side facing the MEMS driver; an end of the second support part away from the first support part is fixed to the reinforcing plate.
